(19) United States
(12) Patent Application Publication
(10) Pub. No.: US 2004/0106288 A1
(43) Pub. Date: Jun. 3, 2004

(54) Method for manufacturing circuit devices

(76) Inventors: Yusuke Igarashi, Gunma (JP); Noriaki Sakamoto, Gunma (JP)

Correspondence Address: FISH & RICHARDSON P.C., 45 ROCKEFELLER PLAZA, SUITE 2800, NEW YORK, NY, 10111, US

(21) Appl. No.: 10/667,771

(22) Filed: Sep. 22, 2003

(30) Foreign Application Priority Data
Sep. 26, 2002 (JP) P. 2002-281888

(51) Int. Cl. H01L 21/302; H01L 21/461

(52) U.S. Cl. 438/689

(57) ABSTRACT

Semiconductor devices wherein a flexible sheet with a conductive pattern was employed as a supporting substrate, a semiconductor element was mounted thereon, and the ensemble was molded have been developed. In this case, problems occur in that a multilayer wiring structure cannot be formed and warping of the insulating resin sheet in the manufacturing process is prominent. In order to solve these problems, a laminated plate 10 in which a thin, first conductive film 11 and a thick, second conductive film 12 have been laminated via a third conductive film 13 is used. In a step for forming a first conductive wiring layer 11A by etching the first conductive film 11, etching depth can be controlled by a stop of etching at the third conductive film 13. Accordingly, forming the first conductive film 11 thin makes it possible to form the first conductive wiring layer 11A into a fine pattern. In addition, since a second conductive wiring layer 14A is formed via a first insulating layer 15, multilayer wiring can be realized.

### BACKGROUND OF THE INVENTION

1. Field of the Invention

The present invention relates to a method for manufacturing circuit devices, and particularly, to a method for forming a low-profile circuit device having a multilayer wiring structure, using two conductive films laminated via a third conductive film to serve as a barrier layer in an etching step.

2. Description of the Related Art

In recent years, IC packages have increasingly been used in portable equipment and small-sized high-density mounting equipment, and conventional IC packages and mounting concepts have undergone drastic changes.

In FIG. 19 through FIG. 21, a flexible sheet 50 is employed as an interposer substrate. Herein, drawings shown in the upper part of the respective drawings are plan views, drawings shown in the lower part are sectional views along a line A-A.

First, on the flexible sheet 50 shown in FIG. 19, a copper foil pattern 51 is prepared by being adhered via an adhesive. This copper foil pattern 51 is different in its pattern depending on whether a semiconductor element to be mounted is a transistor or an IC, and in general, bonding pads 51A and an island 51B are formed. In addition, a symbol 52 shows an opening portion to lead out an electrode from the rear surface of the flexible sheet 50, and the copper foil pattern 51 is exposed therethrough.

Next, this flexible sheet 50 is transferred to a die bonder, and as shown in FIG. 20, semiconductor elements 53 are mounted. Thereafter, this flexible sheet 50 is transferred to a wire die bonder, and the bonding pads 51A and pads of the semiconductor elements 53 are electrically connected by metal wires 54.

Lastly, as in FIG. 21A, a sealing resin 55 is provided on the front surface of the flexible sheet 50 for sealing. Herein, transfer molding is performed so as to cover the bonding pads 51A, island 51B, semiconductor element 53, and metal wires 54.

Thereafter, as shown in FIG. 21B, connecting means 56 such as solder or solder balls are provided, and as a result of a pass through a solder reflow furnace, spherical solder 56 fusion-bonded with the bonding pads 51A via the opening portions 52 are formed. In addition, since the semiconductor elements 53 are formed in a matrix shape on the flexible sheet 50, dicing is performed as in FIG. 17 to separate the semiconductor elements individually.

In addition, in the sectional view shown in FIG. 21C, 51A and 51D are formed as electrodes on both surfaces of the flexible sheet 50. In general, this flexible sheet 50 is supplied after patterning of both surfaces by a manufacturer.

A semiconductor device using the above-described flexible sheet 50 uses no widely-known metal frame and, therefore, has an advantage such that an extremely small-sized low-profile package can be realized, however, substantially, wiring is carried out by only one-layer copper pattern 51 provided on the front surface of the flexible sheet 50. Therein exists a problem such that, since the flexible sheet is flexible, distortion occurs before and after a pattern formation of a conductive film, and this is not suitable for a multilayer wiring structure since displacement between laminated layers is great.

In order to improve supporting strength to suppress the sheet distortion, it is necessary to sufficiently thicken the flexible sheet 50 to approximately 200 μm, and this goes against a reduction in thickness.

Furthermore, in terms of a manufacturing method, in the aforementioned manufacturing devices, for example, in the die bonder, wire bonder, transfer molding device, reflow furnace, etc., the flexible sheet 50 is transferred and attached to a part called a stage or a table.

However, when the thickness of an insulating resin to serve as a base of the flexible sheet 50 is reduced to approximately 50 μm, if the thickness of the copper foil pattern 51 formed on the front surface is also thin such as 9-35 μm, transferring characteristics are considerably inferior due to warping as shown in FIG. 19, and attaching characteristics to the aforementioned stage or table are inferior, therein exists a drawback. This is considered to be warping owing to that the insulating resin itself is considerably thin and warping owing to a difference in the thermal expansion coefficient between the copper foil pattern 51 and insulating resin.

In addition, since the part of the opening portions 52 is pressured from the upside during molding, a force to warp the circumferences of the bonding pads 51A upward may act to deteriorate the bonding pads 51A in adhesive properties.

In addition, if the resin material itself to form a flexible sheet 50 lacks flexibility or if a filler is mixed to enhance thermal conductivity, the flexible sheet 50 becomes rigid. In this condition, when bonding is performed by a wire bonder, the bonding part may crack. In addition, during transfer molding, the part where the metal mold is brought into contact may crack. This appears more prominently if warping exists as shown in FIG. 22.

Although the flexible sheet 50 described above is a flexible sheet on whose rear surface no electrode is formed, an electrode 51D may be formed, as shown in FIG. 21C, on the rear surface of the flexible sheet 50, as well. In this case, since the electrode 51D is brought into contact with the manufacturing devices or is brought into contact with the transferring surfaces of transferring means between the manufacturing devices, there exists a problem such that damage occurs to the rear surface of the electrode 51D. Since the electrode is formed with this damage included, there also exist problems, such that the electrode 51D itself cracks afterward by a heat application and solder wettability declines in a solder connection to a motherboard.

In addition, during transfer molding, a problem also occurs such that a sufficient sealing structure cannot be realized because of weak adhesive properties between the flexible sheet 50 and copper foil pattern 51 and the insulating resin.

### SUMMARY OF THE INVENTION

In order to solve such problems, the present inventors have proposed using a laminated plate formed by laminating a thin first conductive film and a thick second conductive film via a third conductive film.

One of the objects of the present invention is to provide a method for manufacturing circuit devices comprises: a step for preparing a laminated plate by laminating a first conductive film and a second conductive film via a third conductive film; a step for forming a first conductive wiring layer by etching the first conductive film into a desirable pattern; a step for selectively removing the third conductive film by use of the first conductive wiring layer as a mask; a step for laminating an insulating sheet where a first insulating layer has been fitted to a fourth conductive film so that the first insulating layer covers front-surface portions of the second conductive film exposed by removing the third conductive film, the first conductive wiring layer, and end faces of the third conductive film; a step for forming a second conductive wiring layer by etching the fourth conductive film into a desirable pattern; a step for forming multilayer connecting means and thus electrically connecting the first conductive wiring layer with the second conductive wiring layer; a step for covering the second conductive wiring layer with a second insulating layer; a step for forming exposed portions by selectively exposing the second conductive wiring layer by partially removing the second insulating layer; a step for fixedly fitting semiconductor elements onto the second insulating layer to electrically connect the semiconductor elements with the second conductive wiring layer; a step for covering the semiconductor elements with a sealing resin layer; a step for removing the second conductive film to expose the third conductive film on the rear surface; and a step for forming external electrodes at desirable positions of the third conductive film.

Preferably, the conductive wiring layer is formed fine by performing etching up to the third conductive film.

Preferably, a solution to etch only the first conductive film is used.

Preferably, as the solution for performing the etching, a solution containing ferric chloride or cupric chloride is used.

Preferably, the third conductive film is removed by electrolytic peeling.

Preferably, the third conductive film is removed by etching by use of a solution to etch only the third conductive film.

Preferably, the solution is an iodine-based solution.

Preferably, the second conductive film is entirely etched.

Preferably, the second conductive film is formed thicker than the first conductive film.

Preferably, the insulating layer is a thermoplastic resin, a thermosetting resin, or a photosensitive resin.

Preferably, the first conductive film and the second conductive film are metals made of copper as a main material, and the third conductive film is a metal made of silver as a main material.

Preferably, the laminated plate is manufactured by laminating the third conductive film and the first conductive film by electroplating while using the second conductive film as a base.

Preferably, the laminated plate is formed by rolling and joining.

Preferably, the exposed and plated, first conductive film part and electronic components excluding semiconductor elements are electrically connected.

Preferably, the insulating sheet is formed by vacuum press or vacuum lamination.

Preferably, the insulating layer is partially removed by laser processing.

Preferably, the insulating layer is partially removed by a lithographic step.

Preferably, by electrolytic plating using the second conductive layer as an electrode, a metal mainly of copper is built up in through holes formed by partially removing the first insulating layer, and the first conductive wiring layer and the second conductive wiring layer are thus connected.

According to the preferred embodiment, in the step for forming the first conductive wiring layer 11A by etching the thinly formed first conductive film 11, etching can be stopped at a predetermined depth by providing the third conductive film 13 as a barrier layer. Accordingly, an advantage is provided such that the first conductive wiring layer 11A can be formed fine by thinly forming the first conductive film 11. Furthermore, since the second conductive wiring layer 14A is also formed fine via the first insulating layer 15, multilayer wiring can be realized.

Furthermore, in the step for entirely removing the second conductive film 12 by etching from its rear surface, the third conductive film 13 functions as a barrier layer, whereby the rear surface composed of the insulating layer 15 and the third conductive film exposed therethrough can be formed flat, therein exists an advantage. Thus, flatness of the rear surface of the circuit device of a finished product can be improved, therefore, quality of the same can be improved.

### DESCRIPTION OF THE DRAWINGS

FIG. 1 is a sectional view showing a method for manufacturing circuit devices of the preferred embodiment;

FIG. 2 is a sectional view showing a method for manufacturing circuit devices of the preferred embodiment;

FIG. 3 is a sectional view showing a method for manufacturing circuit devices of the preferred embodiment;

FIG. 4 is a sectional view showing a method for manufacturing circuit devices of the preferred embodiment;

FIG. 5 is a sectional view showing a method for manufacturing circuit devices of the preferred embodiment;

FIG. 6 is a sectional view showing a method for manufacturing circuit devices of the preferred embodiment;

FIG. 7 is a sectional view showing a method for manufacturing circuit devices of the preferred embodiment;

FIG. 8 is a sectional view showing a method for manufacturing circuit devices of the preferred embodiment;

FIG. 9 is a sectional view showing a method for manufacturing circuit devices of the preferred embodiment;

FIG. 10 is a sectional view showing a method for manufacturing circuit devices of the preferred embodiment;

FIG. 11 is a sectional view showing a method for manufacturing circuit devices of the preferred embodiment;

FIG. 12 is a sectional view showing a method for manufacturing circuit devices of the preferred embodiment;

FIG. 13 is a sectional view showing a method for manufacturing circuit devices of the preferred embodiment;

FIG. 14 is a sectional view showing a method for manufacturing circuit devices of the preferred embodiment;

FIG. 15 is a sectional view showing a method for manufacturing circuit devices of the preferred embodiment;

FIG. 16 is a sectional view showing a method for manufacturing circuit devices of the preferred embodiment;

FIG. 17 is a plan view showing a circuit device manufactured according to the preferred embodiment;

FIG. 18 is a plan view showing a circuit device manufactured by the preferred embodiment;

FIG. 19 is a view showing a related method for manufacturing semiconductor devices;

FIG. 20 is a view showing a related method for manufacturing semiconductor devices;

FIG. 21 is a view showing a related method for manufacturing semiconductor devices;

FIG. 22 is a view showing a related flexible sheet.

### DESCRIPTION OF THE PREFERRED EMBODIMENTS

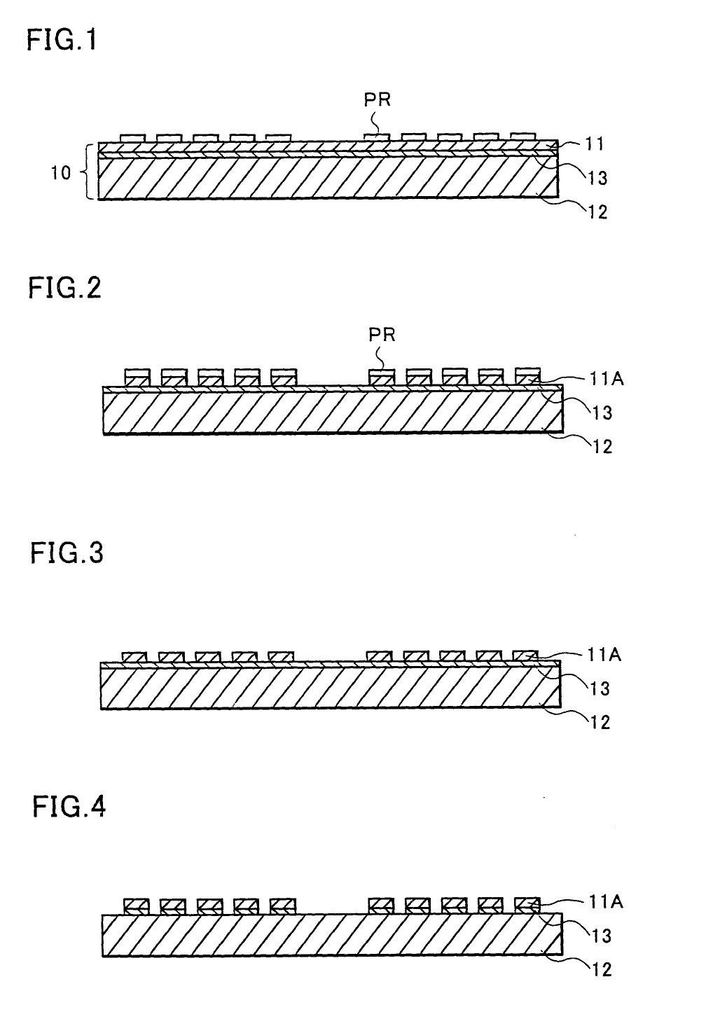

A method for manufacturing circuit devices of the preferred embodiment will be described in detail with reference to FIG. 1 through FIG. 18.

A method for manufacturing circuit devices of the preferred embodiment includes: a step for preparing a laminated plate by laminating a first conductive film and a second conductive film via a third conductive film; a step for forming a first conductive wiring layer by etching the first conductive film into a desirable pattern; a step for selectively removing the third conductive film by use of the first conductive wiring layer as a mask; a step for laminating an insulating sheet where a first insulating layer has been fitted to a fourth conductive film so that the first insulating layer covers front-surface portions of the second conductive film exposed by removing the third conductive film, the first conductive wiring layer, and end faces of the third conductive film; a step for forming a second conductive wiring layer by etching the fourth conductive film into a desirable pattern; a step for forming multilayer connecting means and thus electrically connecting the first conductive wiring layer with the second conductive wiring layer; a step for covering the second conductive wiring layer with a second insulating layer; a step for forming exposed portions by selectively exposing the second conductive wiring layer by partially removing the second insulating layer; a step for fixedly fitting semiconductor elements onto the second insulating layer to electrically connect the semiconductor elements with the second conductive wiring layer; a step for covering the semiconductor elements with a sealing resin layer; a step for removing the second conductive film to expose the third conductive film on the rear surface; and a step for forming external electrodes at desirable positions of the third conductive film. Such respective steps will be described in the following.

The first step of the preferred embodiment is, as shown in FIG. 1, preparing a laminated plate 10 by laminating a thin first conductive film 11 and a thick second conductive film 12 via a third conductive film 13.

On the front surface of the laminated plate 10, the first conductive film 11 is formed substantially throughout the whole area, and the second conductive film 12 is formed substantially throughout the whole area of the rear surface via a third conductive film 13, as well. The first conductive film 11 and second conductive film 12 are, preferably, made of Cu as a main material or are composed of a widely-known lead frame material. The first conductive film 11, second conductive film 12, and third conductive film 13 can be formed by a plating method, an evaporation method, or a sputtering method, or a metal foil formed by a rolling method or a plating method can be adhered to the same. Moreover, as the first conductive film 11 and second conductive film 12, Al, Fe, Fe—Ni, a widely-known lead frame material and the like can be employed.

As the material of the third conductive film 13, a material is employed which is not etched by an etchant used when the first conductive film 11 and second conductive film 12 are removed. In addition, since external electrodes 24 of solder or the like are formed on the rear surface of the third conductive film 13, adhesion of the external electrodes 24 is also considered. Concretely, a conductive film composed of gold, silver, and palladium can be employed as a material of the third conductive film 13.

The first conductive film is formed thin in thickness to form a fine pattern, and the thickness can be approximately 5-35 μm. The second conductive pattern is formed thick to mechanically support the ensemble, and the thickness can be approximately 70-200 μm. The third conductive film 13 functions as a barrier layer when the first conductive film 11 and second conductive film 12 are etched, and is formed with a thickness of approximately 1-10 μm.

The preferred embodiment includes that the second conductive film 12 can be formed thicker than the first conductive film 11. The first conductive film is formed with a thickness of approximately 5-35 μm and is formed as thin as possible so that a fine pattern can be formed. The second conductive film 12 is sufficient with a thickness of approximately 70-200 μm, and providing supporting strength is regarded as important.

Accordingly, by forming the second conductive film 12 thick, flatness of the laminated plate 10 can be maintained, whereby, workability in the following steps can be improved.

Furthermore, the second conductive film 12 is damaged through various steps. However, the thick second conductive film 12 is to be removed in a later step, so that damage is prevented from remaining in a circuit device. In addition, since the sealing resin can be hardened while flatness is maintained, the rear surface of a package can also be flattened, and the external electrodes formed on the rear surface of the laminated plate can also be arranged flat. Therefore, electrodes on a mounting substrate can be brought into contact with the electrodes on the rear surface of the laminated plate 10, whereby a soldering failure can be prevented.

Next, a concrete manufacturing method for the aforementioned laminated plate 10 will be described. A laminated plate 10 can be manufactured by lamination by electroplating or by rolling and joining. When a laminated plate 10 is manufactured by electroplating, first, a second conductive film 12 is prepared. Then, electrodes are provided on the rear surface of the second conductive film 12, and a third conductive film is laminated by an electrolytic plating method. Thereafter, similarly by an electrolytic plating method, a first conductive film is laminated on the third conductive film. When a laminated plate 10 is manufactured by rolling, a first conductive film 11, a second conductive film 12, and a third conductive film 13 which have been prepared in a plate shape are joined by applying pressure and heat by a roll or the like.

The second step of the preferred embodiment is, as shown in FIG. 2 and FIG. 3, forming a first conductive wiring layer 11 by etching the first conductive film 11 into a desirable pattern.

The first conductive film 11 is covered with a photoresist PR of a desirable pattern, and a conductive wiring layer 11A to form bonding pads and wiring is formed by chemical etching. Since the first conductive film 11 is made of Cu as a main material, ferric chloride or cupric chloride is sufficient as an etchant. As a result of etching of the first conductive film 11, the third conductive film 13 also comes into contact with the etchant, however, since the material for the third conductive film 13 is not etched by ferric chloride or cupric chloride, etching stops on the front surface of the third conductive film 13. Thus, since the first conductive film 11 has been formed with a thickness of approximately 5-35 μm, the first conductive wiring layer 11A can be formed into a fine pattern of 50 μm or less. In addition, as shown in FIG. 3, the resist PR is removed after the first conductive wiring layer 11A is formed.

In the preferred embodiment, etching is stopped at the third conductive film 13 in a step for etching the first conductive film 11. The first conductive film 11 to be etched in this step is formed mainly of Cu, and ferric chloride or cupric chloride is used as an etchant to partially remove the Cu. In contrast thereto, since the third conductive film 13 is formed of a conductive material which is not etched by ferric chloride or cupric chloride, etching stops at the front surface of the conductive film 13. As the material for the third conductive film 13, gold, silver, and palladium can be employed.

The third step of the preferred embodiment is, as shown in FIG. 4, for selectively removing the third conductive film 13 by use of the first conductive wiring layer 11A as a mask.

The third conductive film 13 is selectively removed by use of, as a mask, the first conductive wiring layer 11A formed of the first conductive film 11 in the previous step. Two methods can be employed for selectively removing the third conductive film 13. A first method thereof is an etching method by use of a solution to remove only the third conductive film 13. A second method thereof is a method for removing only the third conductive film 13 by electrolytic peeling.

As the first method, a method for partially removing the third conductive film 13 by etching will be described. As an etchant used in this method, an etchant is employed which etches the third conductive film 13 and does not etch the first conductive wiring layer 11A or second conductive film 12. For example, in a case where the first conductive wiring layer 11A and second conductive film 12 are formed of a material mainly of Cu and the third conductive film 13 is an Ag film, only the third conductive film 13 can be removed by using an iodine-based etchant. As a result of etching of the third conductive film 13, the second conductive film 12 comes into contact with the iodine-based etchant, however, the second conductive film 12 made of, for example, Cu is not etched by the iodine-based etchant. Accordingly, etching herein performed stops at the front surface of the second conductive film 12. Herein, the resist PR of FIG. 2 can be removed after this step.

As the second method, a method for removing only the third conductive film 13 by electrolytic peeling will be described. First, a solution containing metal ions is brought into contact with the third conductive film 13. Then, a positive electrode is provided in the solution, a negative electrode is provided on the laminated plate 10, and a direct current is applied. Thereby, only the third conductive film 13 is removed based on a principle reverse to that of plating film formation by an electrolytic method. The solution herein used is a solution used when the material composing the third conductive film 13 is plated. Accordingly, in this method, only the third conductive film 13 is peeled.

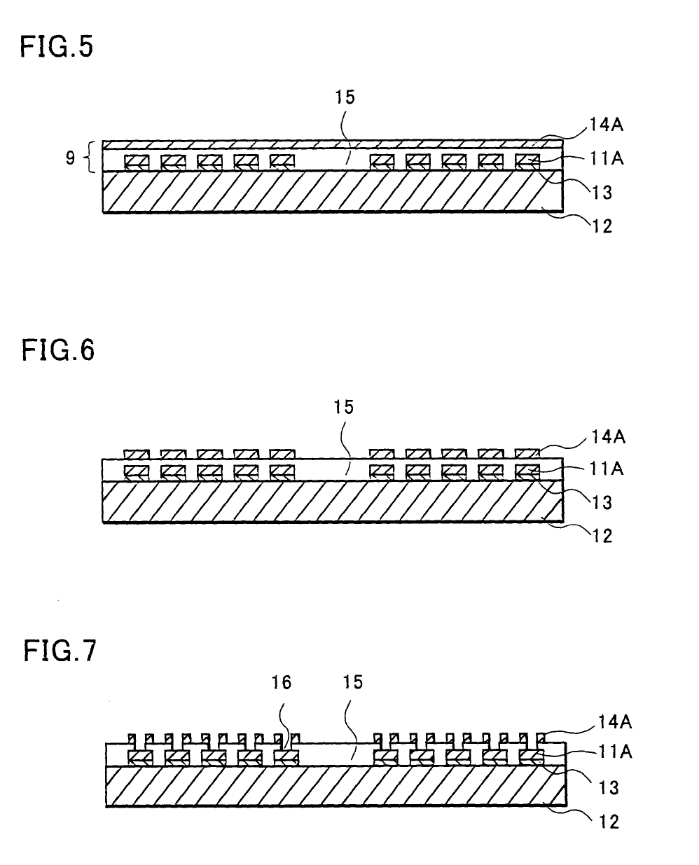

The fourth step of the preferred embodiment is, with reference to FIG. 5, laminating an insulating sheet 9 where a first insulating layer 15 has been fitted to a fourth conductive film 14 so that the first insulating layer 15 covers the first conductive wiring layer 11A and the third conductive film 13.

Referring to FIG. 5, the third conductive film 13, first conductive wiring layer 11A, and partially exposed surface of the second conductive film 12 are covered with the first insulating layer 15. Concretely, the side faces of the partially removed third conductive film 13 and the upper face and side faces (end faces) of the partially removed first conductive wiring layer 11A are covered with the first insulating layer 15. In addition, the front surface of the partially exposed second conductive film 12 is also covered with the first insulating layer 15. A covering by the insulating sheet 9 of this step can be carried out by a vacuum press or laminating method. A vacuum press is a method for overlapping the insulating sheet 9 with the laminated plate 10 and pressing the same in vacuo, and a plurality of laminated sheets 10 can be processed in a lump. In a laminating method, the insulating sheet 9 is laminated by means of a roller. In the laminating method, although after-curing is carried out in a separate step by batch processing, an advantage such that the thickness can be accurately controlled is provided. In addition, after forming only the first insulating layer 15 by the above method, the fourth conductive film 14 may be formed by electroless plating or electrolytic plating.

The fifth step of the preferred embodiment is, with reference to FIG. 6 and FIG. 7, for forming a second conductive wiring layer 14A by etching the fourth conductive film 14 into a desirable pattern.

Referring to FIG. 6, a second conductive wiring layer 14A is formed by partially removing the fourth conductive film 14 in an etching step. Since the fourth conductive film 14 has been formed thin and etching stops at the first insulating layer, the second conductive wiring layer 14A can be formed fine. Herein, since the fourth conductive film 14 has been formed with a thickness of approximately 5-35 μm, the second conductive wiring layer 14A can be formed into a fine pattern of 50 μm or less.

Next, referring to FIG. 7, the first conductive wiring layer 11A is partially exposed by forming through holes 16. For parts where these through holes 16 are to be formed, the fourth conductive film 14 is removed by etching simultaneously with the formation of the second conductive wiring layer 14. Since the second conductive wiring layer 14A is made of Cu as a main material, chemical etching is performed while using ferric chloride or cupric chloride as an etchant. The aperture diameter of the through holes 16 is herein approximately 50-100 μm, although this changes according to resolution in photolithography. In addition, during this etching, the second conductive film 4 is covered by an adhesive sheet or the like for protection from the etchant. However, the second conductive film 4 may be slightly etched if the second conductive film 4 itself is sufficiently thick and has a film thickness for which flatness can be maintained after etching. Moreover, as the second conductive wiring layer 14A, Al, Fe, Fe—Ni, a widely-known lead frame material and the like can be employed.

Subsequently, after removing the photoresist, by use of the second conductive wiring layer 14A as a mask, the first insulating layer 15 immediately under the through holes 16 is removed by a laser to expose the front surface of the first conductive wiring layer 11A on the bottom of the through holes 16. As a laser, a carbon dioxide laser is preferable. In addition, if residue exists at the bottom portion of the aperture portion after the insulating resin is evaporated by the laser, this residue is removed by wet etching with sodium permanganate, ammonium persulfate or the like.

Moreover, in the present step, in a case where the second conductive wiring layer 14A is thin, namely, 10 μm or less, the through holes 16 can be formed by a carbon dioxide laser through the second conductive wiring layer 14A and first insulating layer 15 in a lump after covering the surface excluding the through holes 16 with a photoresist. In this case, a blackening step for roughening the front surface of the second conductive wiring layer 14A is required in advance.

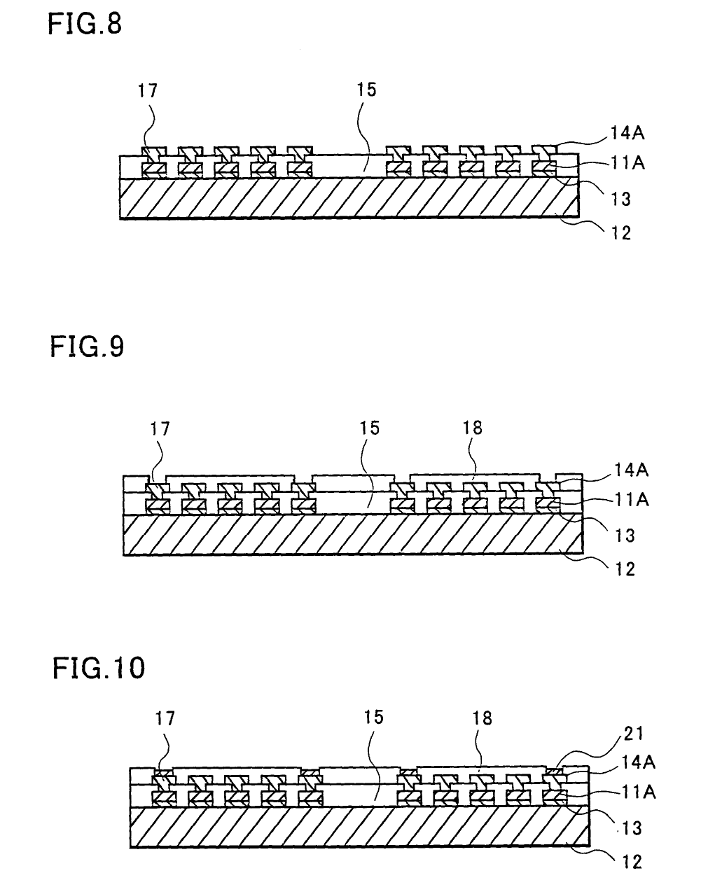

The sixth step of the preferred embodiment is, with reference to FIG. 8, for forming multilayer connecting means 17 and thus electrically connecting the first conductive wiring layer 11A with the second conductive wiring layer 14A.

A plating film, which is multilayer connecting means 17 for electrical connection between the second conductive wiring layer 14A and conductive wiring layer 11A, is formed on the whole surface of the first conductive wiring layer 11A including the through holes 16. This plating film can be formed by both electroless plating and electrolytic plating, and herein, by electrolytic plating by use of the second conductive film 12 as an electrode, a plating film is formed until the second conductive wiring layer 14A and the upper face of the plating are connected and reach a flat condition. At this time, the second conductive layer 12 and the rear surface excluding a plating electrode lead-out portion are protected by a resist to avoid the plating from adhering. This resist is unnecessary in partial jig plating where a front-surface plating portion is surrounded by a jig. Thereby, the through holes 16 are filled up with Cu and multilayer connecting means 17 are formed. In addition, for the plating film, Cu has been herein employed, however, Au, Ag, Pd and the like may be employed.

The seventh step of the preferred embodiment is, with reference to FIG. 9, covering the second conductive wiring layer 14A with a second insulating layer 18.

Referring to FIG. 9, a covering by the second insulating layer 18 can be carried out with a resin sheet by a vacuum press or laminating method, or a liquid resin can be applied by printing or by a roll coater or dip coater. A vacuum press is a method for overlapping a prepreg sheet made of a thermosetting resin and pressing the same in vacuo. A plurality of laminated plates 10 can be processed in a lump. In a laminating method, a thermosetting resin sheet is adhered to each laminated plate 10 by means of a roller. In this method, although after-curing is carried out in a separate process by batch processing, an advantage such that the thickness can be accurately controlled is provided. In addition, the liquid resin is dried after being applied by each method.

The eighth step of the preferred embodiment is, with reference to FIG. 10, forming exposed portions by selectively exposing the second conductive wiring layer 14A by partially removing the second insulating layer 18.

Referring to FIG. 10, for electrical connection with semiconductor elements 19 scheduled to be mounted on the second insulating layer 18, the second insulating layer 18 is partially removed to expose the second conductive wiring layer 14A. The exposed second conductive wiring layer 14A is of parts to become bonding pads. If the second insulating layer 18 is made of a photosensitve material, the second insulating layer 18 may be partially removed by a widely-known lithographic step. In addition, the second insulating layer 18 may also be partially removed by a laser. As a laser, a carbon dioxide laser is preferable. In addition, if residue exists at the bottom portion of the aperture portion after the second insulating layer 18 is evaporated by the laser, this residue is removed by wet etching with sodium permanganate, ammonium persulfate or the like.

Next, a plating layer 21 is formed on the front surface of the second conductive wiring layer 14A to be exposed and become bonding pads. Formation of the plating layer 21 can be performed by adhering gold or silver by an electroless plating method or an electrolytic plating method. In the present embodiment, an Au film is formed by an electroless plating method.

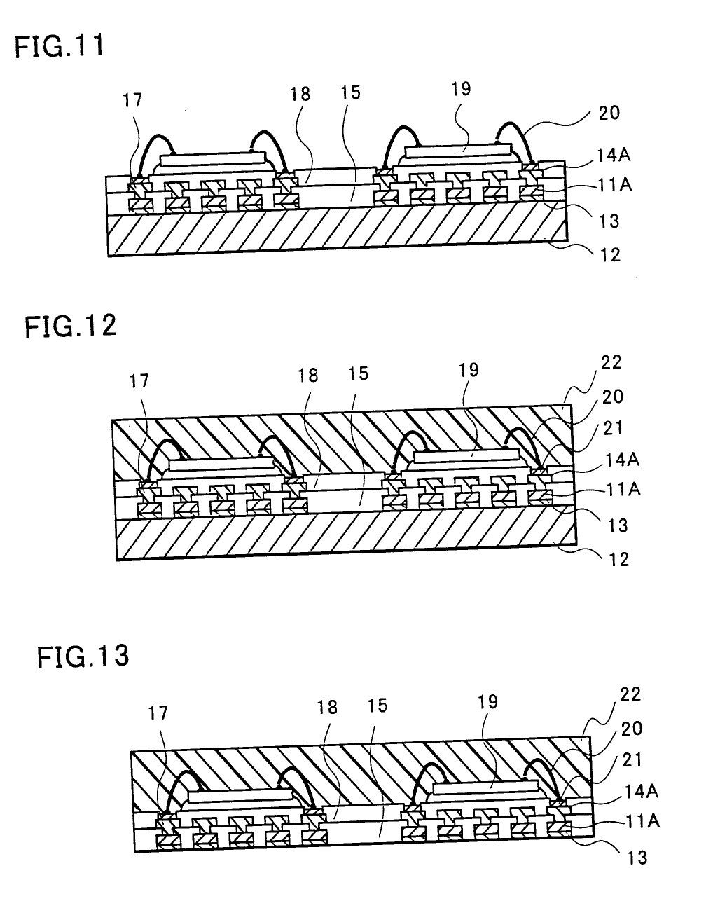

The ninth step of the preferred embodiment is, with reference to FIG. 11, fixedly fitting semiconductor elements 19 onto the second insulating layer 18 to electrically connect the semiconductor elements 19 with the second conductive wiring layer 14A.

The semiconductor elements 19 are, while remaining bare chips, die-bonded onto the second insulating layer 18 with an insulating adhesive resin. Since the semiconductor elements 19 are electrically insulated from the underlying second conductive wiring layer 14A by the second insulating layer 18, the second conductive wiring layer 14A can be freely wired even below the semiconductor elements 19, whereby a multilayer wiring structure can be realized.

In addition, the respective electrode pads of the semiconductor element 19 are connected to bonding pads as part of the surrounding second conductive wiring layer 14A via bonding wires 20. The semiconductor element 19 can be mounted face-down. In this case, solder balls or bumps are provided on the front surfaces of the respective electrode pads of the semiconductor element 19, while on the front surface of the laminated plate 10, electrodes similar to the bonding pads of the second conductive wiring layer 14A are provided at parts corresponding to the solder ball positions.

Now, an advantage of using the laminated plate 10 in wire bonding will be described. In general, when wire bonding is carried out with Au wires, second conductive film 12 is heated at 120° C.-300° C. At this time, if the second conductive film 12 is thin, the laminated plate 10 warps, and in this condition, if the laminated plate 10 is pressurized via a bonding head, there is a possibility that damage occurs to the laminated plate 10. However, these problems can be solved by forming the second conductive film 12 itself thick.

The tenth step of the preferred embodiment is, with reference to FIG. 12, covering the semiconductor elements 19 with a sealing resin layer 22.

The laminated plate 10 is set on a molding device for resin molding. As a molding method, transfer molding, injection molding, coating, dipping and the like can be carried out. However, considering productivity, transfer molding and injection molding are suitable.

In addition, in this step, it is necessary that the laminated plate 10 is brought into contact flat against a lower metal mold of a mold cavity, and the thick, second conductive film 12 performs this function. Moreover, even after removal from the mold cavity, flatness of the package is maintained by the second conductive film 12 until contraction of a sealing resin layer 13 is completely finished. Namely, a role of mechanically supporting the laminated plate 10 until this step is assumed by the second conductive film 12.

The eleventh step of the preferred embodiment is, with reference to FIG. 13, removing the second conductive film 12 to expose the third conductive film 13 on the rear surface.

The second conductive film 12 is etched without masking so that the whole surface is removed. In this etching, chemical etching by use of ferric chloride or cupric chloride is sufficient, and the second conductive film 12 is entirely removed. By thus entirely removing the second conductive film 12, the third conductive film 13 is exposed through the insulating layer 15. As described above, since the third conductive film 13 is formed of a material which is not etched by a solution to etch the second conductive film 12, the third conductive film 13 is not etched in this step.

In this step, a rear surface composed of the first insulating layer 15 and third conductive film 13 is formed flat by the third conductive film 13 serving as a barrier layer in a step for removing the second conductive film 12 by etching. Since the second conductive film 12 is entirely removed by etching, the third conductive film 13 also comes into contact with the etchant in the final stage of etching. As described above, the third conductive film 13 is formed of a material which is not etched by ferric chloride or cupric chloride to etch the second conductive film 12 made of Cu. Accordingly, since etching stops at the lower face of the third conductive film 13, the third conductive film 13 functions as an etching barrier layer. Moreover, in and after this step, the ensemble is mechanically supported by the sealing resin layer 22.

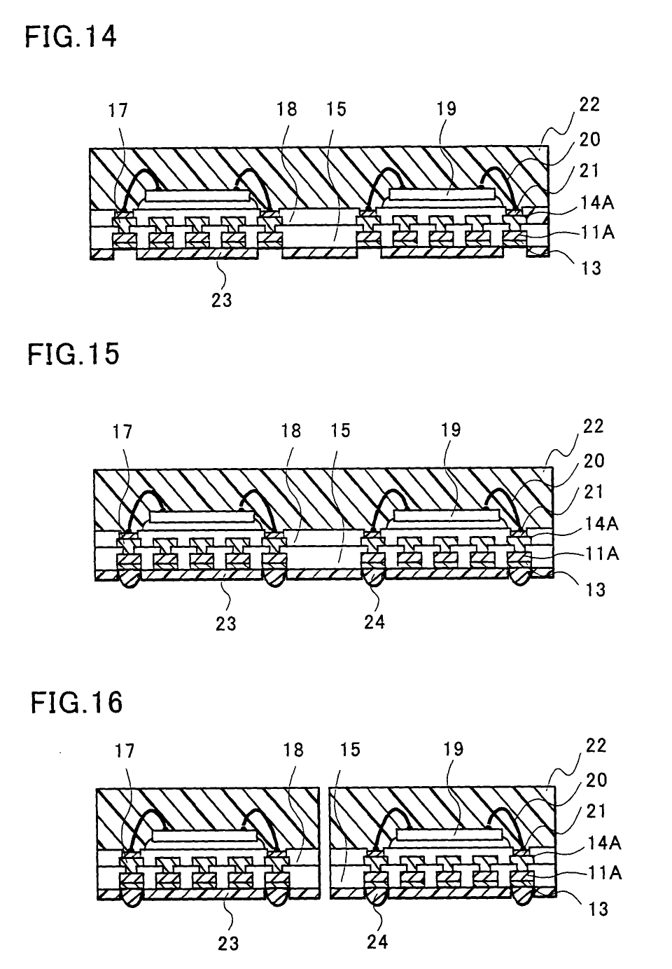

The twelfth step of the preferred embodiment is, with reference to FIG. 14 through FIG. 16, for forming external electrodes 24 at desirable positions of the third conductive film 13.

At this time, for use in an environment where Ag migration is considered to be a problem, it is preferable to remove the third conductive film 13 by selective etching before performing a covering with the insulating sheet 9. First, referring to FIG. 14, the third conductive film 13 is covered with an overcoat 23 by screen-printing with an epoxy resin dissolved in a solvent while exposing parts to form external electrodes 24. If the overcoat resin 23 is made of a photosensitive material, for parts to form external electrodes 24, the overcoat resin 23 can be partially removed by a widely-known lithographic step. Next, referring to FIG. 15, external electrodes 24 are simultaneously formed in these exposed parts by a solder reflow or screen printing with a solder cream.

Lastly, referring to FIG. 16, since a large number of circuit devices are formed on the laminated plate 10 in a matrix fashion, these are separated into individual circuit devices by dicing the sealing resin layer 22 and overcoat resin 23.

In this step, since the third conductive film 13 exposed on the rear surface serves as a plating layer to form external electrodes 24, if the third conductive film 13 is only for the external electrodes 24, a step for newly forming a plating layer can be omitted. In addition, since the circuit devices can be separated into individual circuit devices by only dicing the sealing resin layer 22 and overcoat resin 23 without dicing the Cu part, frictional wear of a dicer to perform dicing can be reduced.

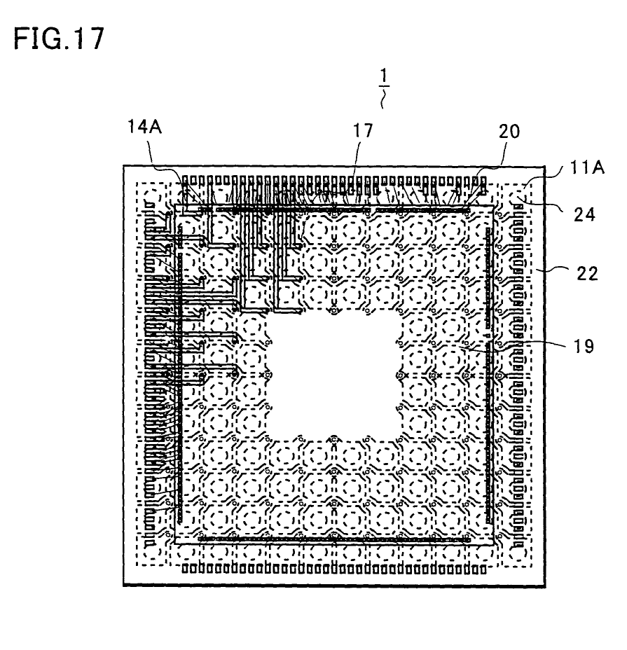

With reference to FIG. 17, a concrete circuit device 1 achieved according to a manufacturing method of the preferred embodiment will be described. The pattern shown by solid lines is a second conductive wiring layer 14A, and the pattern shown by dotted lines is a first conductive wiring layer 11A. The second conductive wiring layer 14A is provided with bonding pads in a manner surrounding the semiconductor element 19, and is partly arranged in two tiers to correspond to the semiconductor element 19 having multiple pads. The bonding pads of the second conductive wiring layer 14A are connected to corresponding electrode pads of the semiconductor element 19 via bonding wires 20, and the fine-pattern, second conductive wiring layer 14A is extended in large numbers from the bonding pads 19 to below the semiconductor element 19 and is connected to the first conductive wiring layer 11A via the multilayer connecting means 17 shown by black circles. In addition, the first conductive wiring layer 11A can also form a fine pattern, therefore, more external electrodes 24 can be formed.

With such a structure, even in a case of a semiconductor element having 200 pads or more, the fine pattern of the second wiring layer 14A can be utilized and extend to a finely patterned, desirable first conductive layer 11A with a multilayer wiring structure, therefore, connection from external electrodes 24 provided in the third conductive film 13 to an external circuit can be carried out.

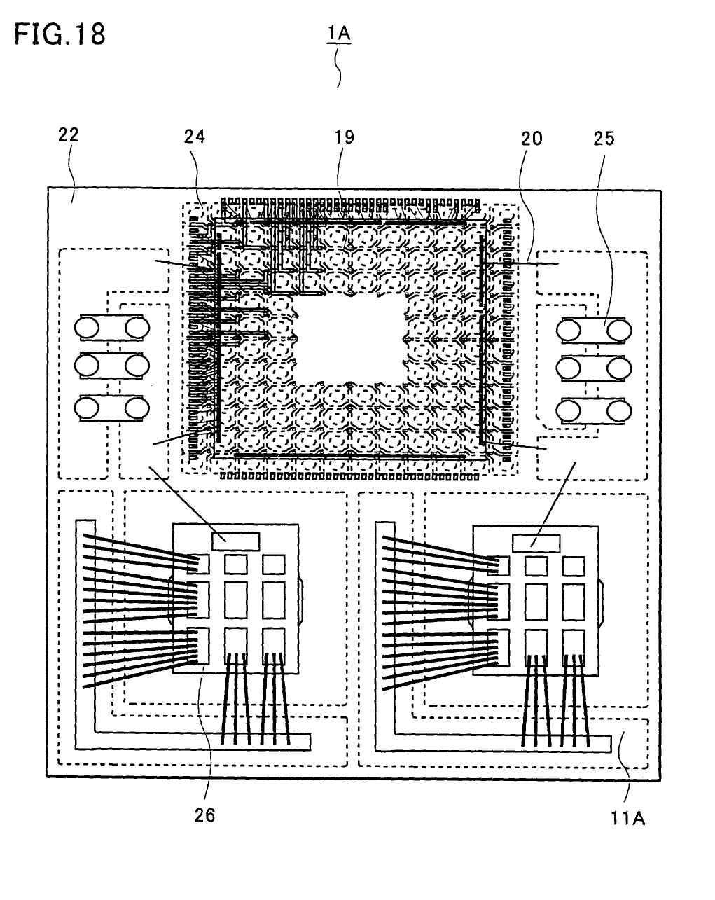

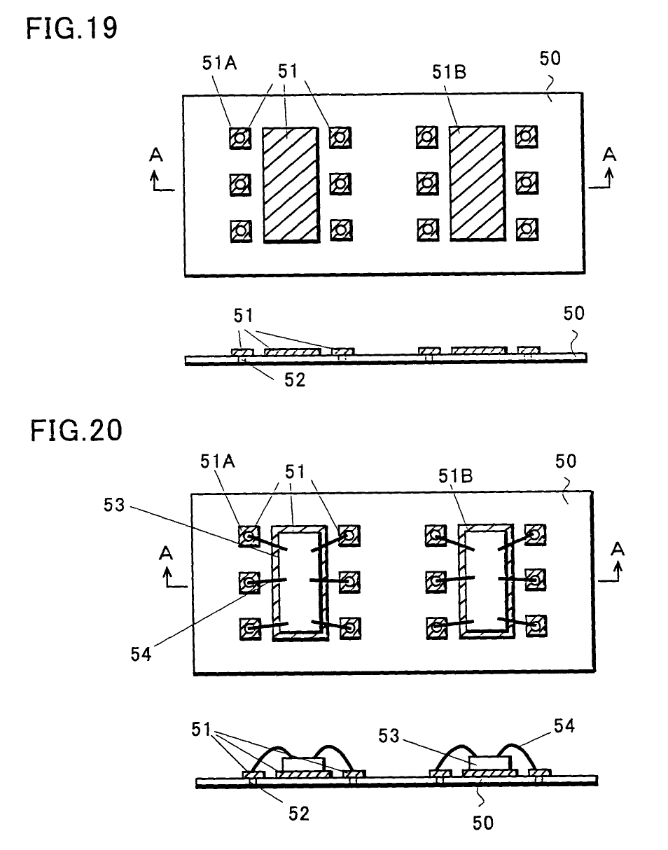

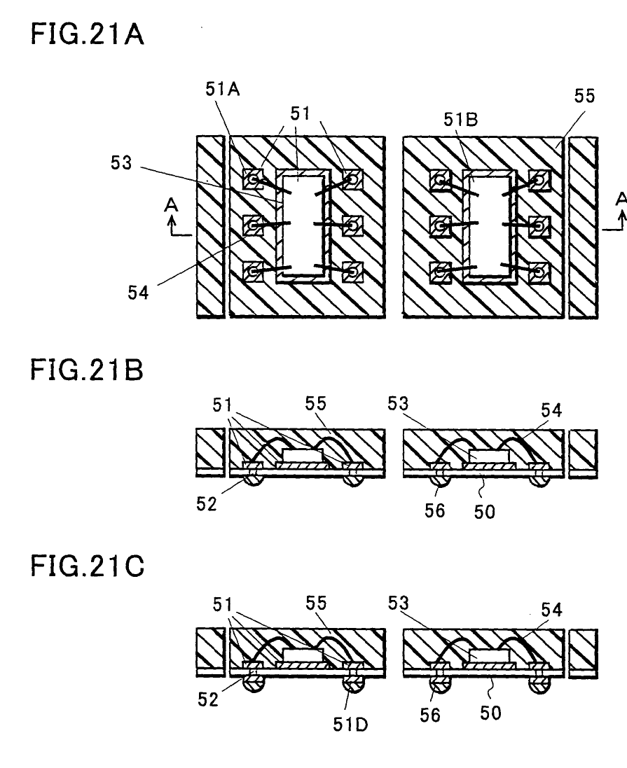

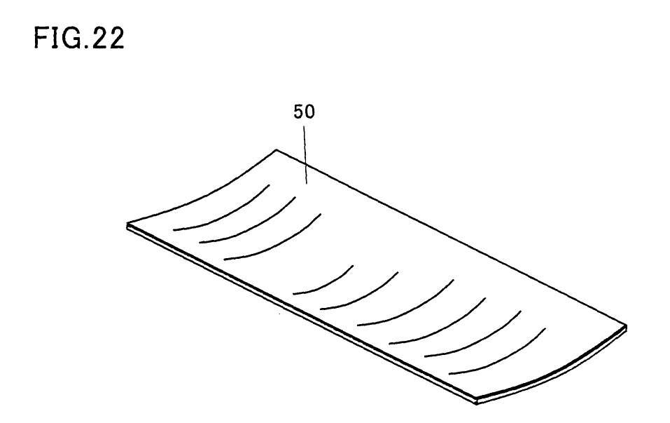

With reference to FIG. 18, a concrete circuit device 1A of another embodiment will be described. Herein, in the circuit device 1A, a second conductive wiring layer 14A shown by dotted lines is formed, and a semiconductor element 19, chip components 25, and bare transistors 26 are mounted on the second conductive wiring layer 14A. For the chip components 25, passive components and active components such as resistors, capacitors, diodes, and coils can be employed in general. In addition, built-in components are electrically connected to each other via a first conductive wiring layer 11A or bonding wires 20. Furthermore, in a position corresponding to the semiconductor element 19, formed is a first conductive wiring layer 11A, therefore, connection from external electrodes 24 provided in the third conductive film 13 to an external circuit can be carried out.

What is claimed is:

1. A method for manufacturing circuit devices comprising:
preparing a laminated plate by laminating a first conductive film and a second conductive film via a third conductive film;
forming a first conductive wiring layer by etching said first conductive film into a desirable pattern;
selectively removing said third conductive film by use of said first conductive wiring layer as a mask;
laminating an insulating sheet where a first insulating layer has been fitted to a fourth conductive film so that said first insulating layer covers front-surface portions of the second conductive film exposed by removing said third conductive film, said first conductive wiring layer, and end faces of the third conductive film;
forming a second conductive wiring layer by etching said fourth conductive film into a desirable pattern;
forming multilayer connecting means and thus electrically connecting said first conductive wiring layer with said second conductive wiring layer;
covering said second conductive wiring layer with a second insulating layer;
forming exposed portions by selectively exposing said second conductive wiring layer by partially removing said second insulating layer;
fixedly fitting semiconductor elements onto said second insulating layer to electrically connect said semiconductor elements with said second conductive wiring layer;
covering said semiconductor elements with a sealing resin layer;
removing said second conductive film to expose said third conductive film on the rear surface.

2. The method for manufacturing circuit devices as set forth in claim 1, wherein
said conductive wiring layer is formed by performing etching up to said third conductive film.

3. The method for manufacturing circuit devices as set forth in claim 1, wherein
a solution to etch said first conductive film is used.

4. The method for manufacturing circuit devices as set forth in claim 3, wherein
as said solution for performing said etching, a solution containing ferric chloride or cupric chloride is used.

5. The method for manufacturing circuit devices as set forth in claim 1, wherein
said third conductive film is removed by electrolytic peeling.

6. The method for manufacturing circuit devices as set forth in claim 1, wherein
said third conductive film is removed by etching by use of a solution to etch said third conductive film.

7. The method for manufacturing circuit devices as set forth in claim 6, wherein
said solution is an iodine-based solution.

8. The method for manufacturing circuit devices as set forth in claim 1, wherein
said second conductive film is entirely etched.

9. The method for manufacturing circuit devices as set forth in claim 1, wherein
said second conductive film is formed thicker than said first conductive film.

10. The method for manufacturing circuit devices as set forth in claim 1, wherein
said insulating layer is a thermoplastic resin, a thermosetting resin, or a photosensitive resin.

11. The method for manufacturing circuit devices as set forth in claim 1, wherein
said first conductive film and said second conductive film are metals made of copper as a main material, and said third conductive film is a metal made of silver as a main material.

12. The method for manufacturing circuit devices as set forth in claim 1, wherein
said laminated plate is manufactured by laminating said third conductive film and said first conductive film by electroplating while using said second conductive film as a base.

13. The method for manufacturing circuit devices as set forth in claim 1, wherein
said laminated plate is formed by rolling.

14. The method for manufacturing circuit devices as set forth in claim 1, wherein
said exposed and plated, first conductive film part and electronic components excluding semiconductor elements are electrically connected.

15. The method for manufacturing circuit devices as set forth in claim 1, wherein
said insulating sheet is formed by vacuum press or vacuum lamination.

16. The method for manufacturing circuit devices as set forth in claim 1, wherein
said insulating layer is partially removed by laser processing.

17. The method for manufacturing circuit devices as set forth in claim 1, wherein
said insulating layer is partially removed by a lithographic method.

18. The method for manufacturing circuit devices as set forth in claim 1, wherein
by electrolytic plating using said second conductive layer as an electrode, a metal mainly of copper is built up in through holes formed by partially removing said first insulating layer, and said first conductive wiring layer and said second conductive wiring layer are thus connected.
